(19) United States
(12) Patent Application Publication
(10) Pub. No.: US 2004/0178856 A1
(43) Pub. Date: Sep. 16, 2004

(54) Continuous-phase oscillator with ultra-fine frequency resolution

(76) Inventor: Zeno Wahl, Leesburg, VA (US)

Correspondence Address: ROBERT M. MCDERMOTT, ESQ., 1824 FEDERAL FARM ROAD, MONTROSS, VA, 22520, US

(21) Appl. No.: 10/779,979

(22) Filed: Feb. 17, 2004

Related U.S. Application Data
(60) Provisional application No. 60/453,402, filed on Mar. 10, 2003.

(51) Int. Cl. H03L 7/00

(52) U.S. Cl. 331/18

(57) ABSTRACT

A high-resolution DDS coupled to a phase-locked-loop (PLL) is provided that tracks the output of the DDS. The output of the PLL is provided to a synthesizer that scales the frequency from the PLL to the desired output frequency. When used to track the output of a DDS at a substantially fixed frequency, the PLL provides an output also at a substantially fixed frequency. The frequency translation of this PLL is chosen such that it allows the DDS to operate at an output frequency range that is spectrally pure. This DDS frequency range is determined either through analysis or found empirically. Once the PLL is ‘locked’ onto the output of the DDS, the output spectrum is filtered by the loop-filter of the PLL, and thus provides a very narrow bandpass filtering effect. If the DDS frequency is changed, the PLL provides a gradual change to the new frequency, thereby providing a gradual phase change through the transition. Consideration of the PLL loop-filter bandwidth and damping factor allow the designer to closely approximate the desired output frequency step response time. Through the transition, the PLL continues to provide a very narrow bandpass filtering effect, thereby providing a narrowband filter whose center frequency varies with the desired output frequency across a relatively wide range.

This application claims the benefit of U.S. provisional patent application 60/453,402, filed 10 Mar. 2003.

### BACKGROUND OF THE INVENTION

1. Field of the Invention

This invention relates to the field of electronics, and in particular to an oscillator that can be tuned to a very precise frequency relative to its oscillation frequency, and provides for phase-coherent frequency adjustment or modulation. The oscillator of this invention is particularly well suited for microwave receivers that require Doppler compensation, such as satellite receivers.

2. Description of Related Art

Communication systems use oscillators to provide a virtual synchronization between a transmitter and receiver. A transmitter modulates an information signal with one or more oscillation signals, and a receiver demodulates the information signal using corresponding, locally generated, one or more oscillation signals. If the oscillation signals at the receiver differ from the oscillation signal at the receiver, distortions are introduced in the demodulated signal.

The controllability of an oscillator is typically characterized by the precision with which the oscillator can be controlled. To achieve ultra-high precision, for example in the order of a few Hertz at a nominal frequency in the order of Gigahertz, direct digital synthesizers (DDSs) are commonly used.

As illustrated in FIG. 1, a high-resolution DDS 120 provides a controllable-frequency output that is filtered by one or more filters 130 to produce an input to a synthesizer 150 that is used to generate an oscillator output Q. The DDS 120 may be, for example, an AD9830 from Analog Devices, Inc., which accepts an input from a reference oscillator 110 up to 50 MHz, and provides a controllable output frequency with a precision of one part in four billion. Typically, the DDS 120 provides an output frequency that is proportional to a given phase increment N. For example, the AD9830 is a “Numerically Controlled Oscillator” (NCO) that has a 32 bit wide phase accumulator that is incremented by N at each reference oscillator 110 clock cycle, each overflow of the accumulator corresponding to one DDS 120 clock cycle. In this manner, the DDS 120 provides an output frequency that is equal to the reference oscillator 110 frequency multiplied by N, and divided by 2³².

The output of the DDS 120 is a step function that approximates a sine wave at the controlled output frequency. A filter 130 provides a continuous sine-wave input to the synthesizer 150. The synthesizer 150 scales the controlled signal from the filter 130 to provide the signal Q at the desired output frequency from a voltage controlled oscillator (VCO) 155. The synthesizer 150 may be, for example, an SPLL-A113 from Synergy Microwave Corporation, that operates in the 2 GHz range. Via the appropriate choice of factors N and M, wherein N determines the DDS output frequency and M determines the scaling of the DDS output frequency, a desired output frequency can be obtained.

In a conventional system, the filters 130 are designed to accommodate the range of the factor N, with a concurrent effect on the effectiveness of the filters 130. A conventional filter exhibits a response curve centered about a nominal center frequency. To accommodate a range of frequencies, the response curve must be wide enough to pass all signals within the range without substantial attenuation. Consequently, a conventional filter 130 that accepts a wide range of input frequencies will allow a correspondingly wide range of noise signals within the wide input bandwidth. Additionally, when the DDS output frequency is adjusted, a conventional wide bandwidth filter will generally introduce a phase shift as the frequency is changed.

Typically, a Hi-Resolution DDS 120 output has low-level Phase modulated spurious output frequencies that can be very close in frequency to the main output, and not filtered by the Low-pass Filter 130. This low-level phase-modulation will be multiplied by the factor M by the Synthesizer PLL 150, and appear in the output Q as relatively high level PM spurs close to the desired output frequency.

In particular applications, such as a satellite communication system, even if a known fixed transmitter frequency is used, the oscillator that is used to provide a receiver frequency corresponding to the fixed transmitter frequency must have a range that accommodates for Doppler shifts of the received frequency as the satellite traverses an area. That is, a satellite receiver typically includes an oscillator that is programmed to change its frequency correspondingly to the change of frequency that will occur due to Doppler effects, and the filters are designed to pass signals within the expected range of these Doppler-induced frequency changes. To maintain phase coherency with the transmitter, these filters must be designed to suppress any transient phase-distortions that may occur as the DDS frequency is changed.

### BRIEF SUMMARY OF THE INVENTION

It is an object of this invention to provide a high-resolution programmable oscillator with high noise-rejection capability. It is a further object of this invention to provide a high-resolution programmable oscillator with a coherent phase response over a range of frequency. It is a further object of this invention to provide a high-resolution programmable oscillator with a bandpass response that is substantially narrower than the oscillator's frequency range. It is a further object of this invention to provide a system that is well suited for satellite communications. It is a further object of this invention to provide a frequency modulator that provides substantially continuous phase response.

These objects and others are achieved by providing a high-resolution DDS coupled to a phase-locked-loop (PLL) that tracks the output of the DDS. The output of the PLL is provided to a synthesizer that scales the frequency from the PLL to the desired output frequency. When used to track the output of a DDS at a substantially fixed frequency, the PLL provides an output also at a substantially fixed frequency. Once the PLL is ‘locked’ onto the output of the DDS, it is substantially unaffected by signals at different frequencies from the DDS output frequency, and thus provides a very narrow bandpass filtering effect. If the DDS frequency is changed, the PLL provides a gradual change to the new frequency, thereby providing a gradual phase change through the transition. Through the transition, the PLL continues to provide a very narrow bandpass filtering effect, thereby providing a narrowband filter whose center frequency varies with the desired output frequency across a relatively wide range.

### BRIEF DESCRIPTION OF THE DRAWINGS

The invention is explained in further detail, and by way of example, with reference to the accompanying drawings wherein:

FIG. 1 illustrates an example prior art high-resolution oscillator.

FIG. 2 illustrates an example high-resolution oscillator in accordance with this invention.

FIG. 3 illustrates further details of an example high-resolution oscillator in accordance with this invention.

FIG. 4 illustrates an example system that includes the example oscillator of this invention.

FIG. 5 illustrates another example system that includes the example oscillator of this invention.

Throughout the drawings, the same reference numerals indicate similar or corresponding features or functions.

### DETAILED DESCRIPTION OF THE INVENTION

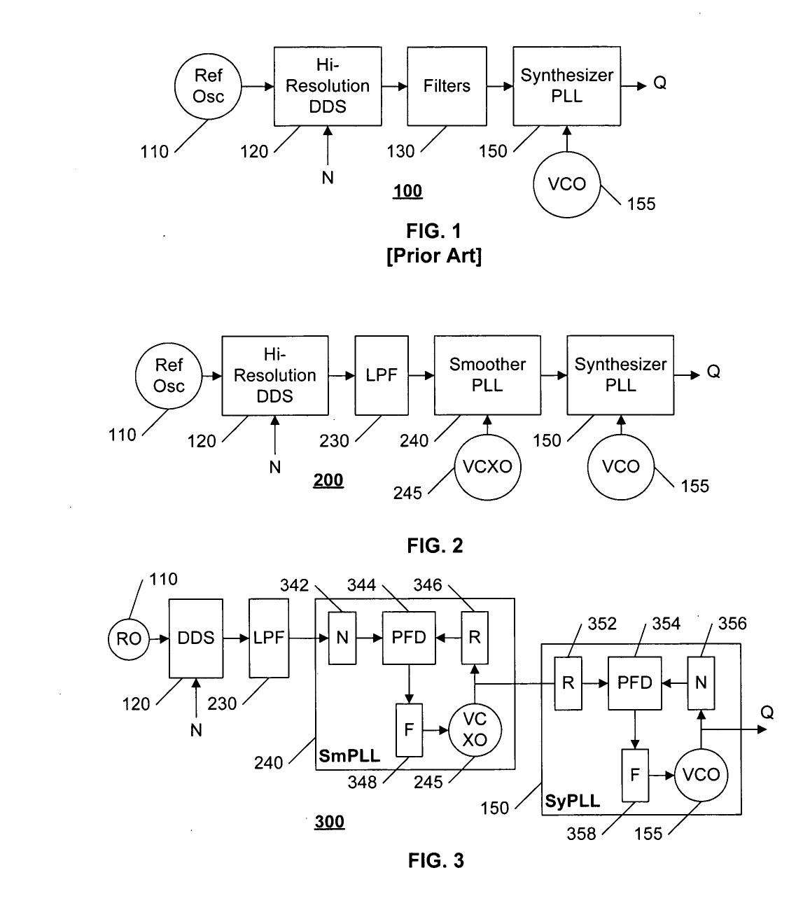

FIG. 2 illustrates an example high-resolution oscillator 200 in accordance with this invention. The oscillator 200 includes a DDS 120, a filter 230, a phase-locked-loop (PLL) 240, and a synthesizer 150. As discussed above with regard to the DDS 120 of FIG. 1, the reference oscillator 110 provides a base input frequency that is scaled down based on an input factor N. A low-pass filter (LPF) 230 filters the output of the DDS 120 to produce a sine-wave and to remove aliasing.

In accordance with this invention, the PLL 240 is configured to provide a “clock smoothing” effect. The PLL 240 provides an output frequency from a voltage-controlled oscillator 245 that is proportional to the input frequency from the DDS 120. Preferably, the PLL 240 is configured for near-unity frequency translation, and the oscillator 245 is a voltage controlled crystal oscillator to minimize phase-noise. For convenience, the clock smoother PLL 240 circuit is centered at a common reference frequency, such as 10.000 MHz.

In a preferred embodiment, the DDS frequency is chosen through analysis or empirical testing to find a range of frequencies where the output spurs caused by phase transitions are either non-existent or very low in level, so that when the output of the DDS 120 is scaled up to the output frequency Q, the scaled-up spurious frequencies are non-existent or very low in level. That is, the DDS frequency is analytically or empirically chosen to obtain the best spectral purity at the required output frequency Q. The Smoother PLL 240 provides the required frequency translation so that the target output frequency Q can be met for the range of DDS frequencies where the output spurs are non-existent or very low in level.

When the PLL 240 locks onto the output of the DDS 120, via the LPF 230, the output frequency of the Smoother PLL 240 is not only translated in frequency, but it is also filtered by virtue of the loop filter characteristics of the phase locked loop, thus serving as a very narrow band filter of the output of the DDS 120. Consideration of the smoother PLL loop-filter bandwidth and damping factor allows the designer to closely approximate the desired output frequency Q step-response-time. Thus, in accordance with one aspect of this invention, the designer is provided the ability to manipulate the frequency-step versus time characteristics of the output Q by controlling the smoother PLL loop-filter bandwidth and damping factor.

When the output frequency of the DDS 120 is changed, the PLL 240 tracks this change, constrained only by the controllable range of the oscillator 245. Thus, the PLL 240 provides a narrowband filtering effect across a relatively wide range of frequencies. Additionally, although a change in the DDS frequency occurs in discrete steps, the output of the PLL 240 will provide a smooth and phase-continuous change, by virtue of the analog loop filter characteristics of the Smoother PLL 240, as it adjusts the output frequency of the oscillator 245 in response to the discrete/discontinuous change from the DDS 120. That is, in addition to providing a very narrowband filtering effect, the PLL 240 also smoothes frequency changes and eliminates phase transients.

The filtered and smoothed output of the PLL 240 is provided to a synthesizer 150 to be scaled to the desired output frequency. The synthesizer 150 is preferably a phase-locked-loop device that controls the output of a VCO 155 to the desired output frequency based on the input from the PLL 240 and a programmed scaling factor.

FIG. 3 illustrates an example embodiment 300 of the oscillator 200 of FIG. 2 that is suitable for providing an output frequency in the order of a few Gigahertz, controllable to within a few Hertz.

As in FIG. 1, the DDS 120 of FIG. 3 may be, for example, an AD9830 from Analog Devices, Inc., which accepts an input from a reference oscillator 110 up to 50 MHz, and provides a controllable output frequency with a precision of one part in four billion (232). As discussed above, depending upon the design of the DDS 120, certain incremental frequency transitions will exhibit anomalous phase shifts, termed “spurs”. In a preferred embodiment, the DDS 120 is configured to operate in a “spur-free” band of output frequencies, which is typically determined empirically. In this example embodiment, the AD9830 is configured to operate in a band centered at 9.54545 MHz.

The LPF 230 may be, for example, an SCLF-10.7 from Minicircuits, which converts the output of the DDS 120 to a sine-wave and removes aliasing.

The PLL 240 may be, for example, an ADF4001BRU, from Analog Devices, Inc., and the oscillator 245 is a voltage controlled crystal oscillator (VCXO), such as the Vectron VCUHCA 10.000 MHz oscillator, which exhibits minimal phase-noise and a wide pulling range (+/−100 ppm). In this example, the ADF4001BRU is configured to accept the output of the LPF 230 at its “N” input, because this input is configured to accept low signal levels, such as those provided by the DDS 120. The “R” input of the ADF4001BRU accepts the logic-level output of the voltage controlled crystal oscillator. The ADF4001BRU provides an output at a frequency of R/N times the input frequency from the DDS 120, where R and N are programmable. A frequency divider 342 divides the frequency from the DDS 120 by the factor N, and another frequency divider 346 divides the frequency from the VCXO 245 by the factor R. The outputs of each of the dividers 342, 346 are provided to a phase/frequency difference detector 344, whose output is provided to a filter 348. The output of the filter 348 controls the VCXO 245 until the outputs of the dividers 342 and 346 are the same (Fin/N=Fxo/R), thereby providing an output frequency Fxo=R/N*Fin. In this example embodiment, R/N is set to be near-unity, such as 22/21, to produce an output of 10.000 MHz when the DDS 120 is operated at 9.5454545454 MHz. Any desired scale factor may be used; a scale factor greater than unity will magnify/accentuate the phase noise or spurs at the output of the DDS 120, and a scale factor less than unity will reduce/attenuate such phase noise or spurs. The choice of the particular scale factor will be dependent upon the output characteristics of the DDS 120 at the selected frequency of operation.

As in FIG. 1, the synthesizer 150 and VCO 155 of FIG. 3 may be, for example, an SPLL-A113 from Synergy Microwave Corporation. In this example, the “R” input of the SPLL-A113 is configured to accept the output of the PLL 240, and the “N” input is configured to accept the output of the voltage controlled oscillator VCO 155. The operation of the dividers 352, 356, phase/frequency detector 354, and loop-filter 358 are as discussed above with respect to corresponding devices 346, 342, 344, and 348, respectively, so that the frequency of the VCO 155 is controlled to equal to N/R*Fin. The factors R and N of the synthesizer 150 are selected to provide the desired frequency at the VCO 150. For example, if a 2.0 GHz signal is desired, and the input from the PLL 240 is 10.0 MHz, N should be equal to 200*R.

In the example above, the DDS 120 can be controlled with a step size in the order of milliHertz. With a near-unity scaling at the PLL 240, and a nominal *200 scaling at the synthesizer 150, the 2.0 GHz output of the synthesizer 150 can be controlled to within a few Hertz. With a +/−1 KHz typical range of a VCXO 245, the continuous range of the 2.0 GHz output of the synthesizer 150 is as large as +/−200 KHz, which is particularly well suited for continuous Doppler compensation for satellite communications.

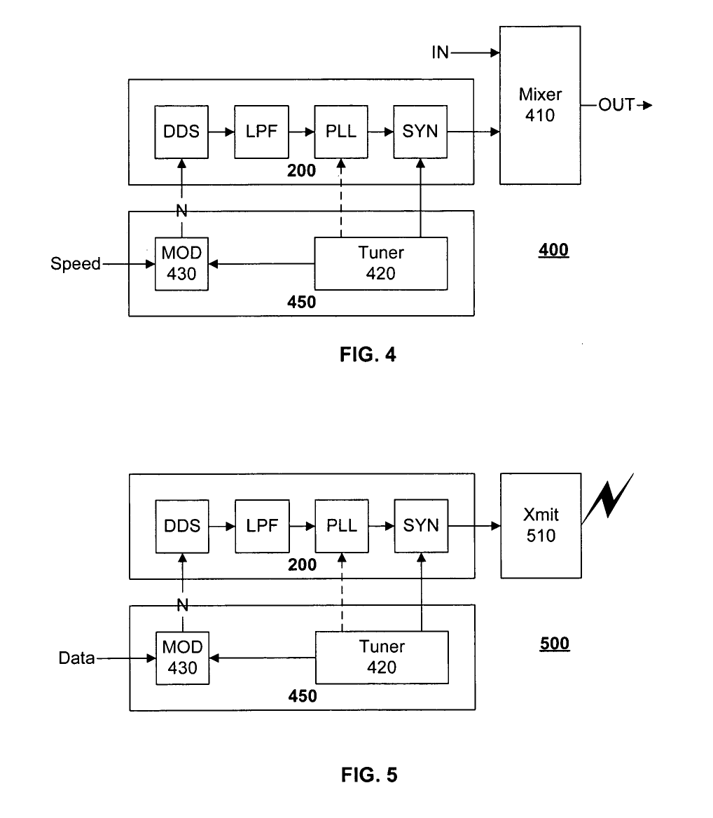

FIG. 4. illustrates an example system 400 that can be configured as a satellite receiver in accordance with this invention. A mixer 410 combines a received input signal IN with an oscillation signal to produce an output signal OUT. A controller 450 controls an oscillator 200 to provide the oscillation signal. In a typical satellite system, the input signal is produced by a transmitter at a fixed frequency, but the received signal's frequency varies due to the Doppler effect caused by the movement of the transmitter relative to the receiver. Within the controller 450, a tuner 420 provides the nominal control parameters to the oscillator 200 to tune the receiver 400 to the fixed transmit frequency. A Doppler modulator 430 adjusts this nominal frequency based on the determined relative speed of the transmitter, so that the output frequency of the oscillator 200 corresponds to frequency of the received input signal, as affected by the Doppler effect. The relative speed may be determined based on the known orbit of the satellite (or orbits, if the receiver and transmitter are both in satellites), or based on telemetry data, or the speed may be measured directly, or via a combination of these methods and others well known in the art.

Note that the configuration of FIG. 4 can also be used as a satellite transmitter, wherein the modulator 430 is configured to apply an inverse of the frequency shift caused by the Doppler effect. The mixer 410 in this embodiment combines the input signal with the oscillation signal to produce an output signal at a varying frequency that is received at the intended receiver at a substantially constant frequency.

Although the modulator 430 is presented as a device that provides a Doppler correction, one of ordinary skill in the art will recognize that the modulator 430 can be configured to adjust a nominal frequency based on any other determinable or measurable parameter that is correlated to a change of frequency about the nominal frequency. Correspondingly, the system 500 illustrated in FIG. 5 can be configured as a transmitter that provides a continuous-phase frequency-modulated output (CPFM), wherein the input to the modulator 430 is the modulating data, and the CPFM output of the oscillator 200 is provided to a transmitter 510. A conventional FM receiver can be used to demodulate the received CPFM using conventional techniques to recover a copy of the modulating data. Or, if the transmitter 500 is used for satellite communications, a Doppler-correcting receiver 400 can be used to demodulate the signal to recover a copy of the modulating data.

The foregoing merely illustrates the principles of the invention. It will thus be appreciated that those skilled in the art will be able to devise various arrangements which, although not explicitly described or shown herein, embody the principles of the invention and are thus within its spirit and scope. For example, the invention is presented in the context of providing phase coherency, and thus the example embodiments include phase-dependent constraints, such as the use of a voltage control crystal oscillator. One of ordinary skill in the art will recognize that the use of other components may provide for a greater frequency range, or other advantages, if the phase-related constraints, or other constraints, are not required for a particular application. These and other system configuration and optimization features will be evident to one of ordinary skill in the art in view of this disclosure, and are included within the scope of the following claims.

I claim:

1. An oscillator comprising:
a direct digital synthesizer (DDS) that provides a controlled frequency output,
a phase-locked-loop (PLL), operably coupled to the DDS, that is configured to provide a tracked frequency output based on the controlled frequency output and a first scale factor,
a scaling synthesizer, operably coupled to the PLL, that is configured to provide an oscillator output based on the tracked frequency output and a second scale factor.

2. The oscillator of claim 1, wherein
the PLL includes a voltage controlled crystal oscillator (VCXO).

3. The oscillator of claim 1, wherein
the scaling synthesizer includes an other phase-locked-loop.

4. The oscillator of claim 1, wherein
the controlled frequency output is within a predetermined frequency band, and
the frequency band is determined based on the characteristics of the DDS to minimize unwanted phase modulation.

5. The oscillator of claim 1, wherein
the PLL is configured to operate with predetermined loop filter characteristics, and
the loop filter characteristics are determined to provide a desired step-response-time at the oscillator output.

6. The oscillator of claim 1, wherein
the DDS includes a numerically controlled oscillator (NCO) that provides the controlled frequency output based on an accumulation of a phase increment factor.

7. The oscillator of claim 6, further including
a low pass filter that is configured to receive the controlled frequency output from the DDS, and to provide therefrom a filtered controlled frequency output to the PLL.

8. A method of providing an oscillation signal, comprising:
generating a first signal at a controlled frequency,
providing a second signal at a frequency that is phase-locked to the first signal,
scaling the frequency of the second signal to produce the oscillation signal.

9. The method of claim 8, wherein
generating the first signal includes a direct digital synthesis of the first signal.

10. The method of claim 9, wherein
scaling the frequency includes phase-locking the oscillation signal to the second signal.

11. A system comprising:
an oscillator that is configured to provide an oscillation signal based on one or more control parameters, and
a controller, operably coupled to the oscillator, that is configured to provide the one or more control parameters, wherein
the oscillator includes:
a direct digital synthesizer (DDS) that provides a controlled frequency output based on the one or more control parameters,
a phase-locked-loop (PLL), operably coupled to the DDS, that is configured to provide a tracked frequency output based on the controlled frequency output and a first scale factor,
a scaling synthesizer, operably coupled to the PLL, that is configured to provide the oscillation signal based on the tracked frequency output and a second scale factor.

12. The system of claim 11, wherein
the PLL includes a voltage controlled crystal oscillator (VCXO).

13. The system of claim 11, wherein
the scaling synthesizer includes an other phase-locked-loop.

14. The system of claim 11, further including
a mixer, operably coupled to the oscillator, that is configured to combine an input signal and the oscillation signal to produce an output signal.

15. The system of claim 14, wherein
the system corresponds to a communications receiver and
the mixer includes a demodulator.

16. The system of claim 15, wherein
the one or more control parameters are provided by the controller based on a velocity of a transmitter of the input signal relative to the communications receiver.

17. The system of claim 11, wherein
the system corresponds to a communications transmitter.

18. The system of claim 17, wherein
the one or more control parameters are provided by the controller based on a velocity of a receiver of the input signal relative to the communications transmitter.

19. The system of claim 11, wherein
the controller is configured to provide the one or more control parameters based on values of an input modulation signal.

20. The system of claim 11, wherein
the controlled frequency output is within a predetermined frequency band, and
the frequency band is determined based on the characteristics of the DDS to minimize unwanted phase modulation.

21. The system of claim 11, wherein
the PLL is configured to operate with predetermined loop filter characteristics, and
the loop filter characteristics are determined to provide a desired step-response-time at the oscillator output.

22. The system of claim 11, wherein
the DDS includes a numerically controlled oscillator (NCO) that provides the controlled frequency output based on an accumulation of a phase increment factor.

23. The system of claim 14, wherein
the oscillation signal has a frequency of at least 1 gigaHertz, and
the frequency of the oscillation signal is controllable with a resolution of less than ten Hertz via a control of the controlled frequency output.

24. The system of claim 23, wherein
a range of the controlled frequency output is in an order of kiloHertz, and
a range of the oscillation signal is in an order of hundreds of kiloHertz.
